(19) United States
(12) Patent Application Publication
(10) Pub. No.: US 2026/0219465 A1
(43) Pub. Date: Jul. 30, 2026

(54) CHIPLET-BASED OPTICAL WAFER-SCALE NETWORK SWITCH

(71) Applicant: Volantis Semiconductor, Inc., Portland, OR (US)

(72) Inventors: Tapabrata Ghosh, San Francisco, CA (US); Kevin Nan Lam, Pleasanton, CA (US)

(73) Assignee: Volantis Semiconductor, Inc., Portland, OR (US)

(21) Appl. No.: 19/461,837

(22) Filed: Jan. 28, 2026

Related U.S. Application Data
(63) Continuation-in-part of application No. 19/387,789, filed on Nov. 13, 2025.
Application No. 19/387,789 is a continuation-in-part of application No. 19/056,456, filed on Feb. 18, 2025.
Application No. 19/056,456 is a continuation-in-part of application No. 19/023,647, filed on Jan. 16, 2025.
Application No. 19/023,647 is a continuation-in-part of application No. 18/978,188, filed on Dec. 12, 2024.
Application No. 18/978,188 is a continuation-in-part of application No. 18/958,107, filed on Nov. 25, 2024.
Application No. 18/958,107 is a continuation-in-part of application No. 18/940,944, filed on Nov. 8, 2024.
(60) Provisional application No. 63/750,822, filed on Jan. 29, 2025.
(60) Provisional application No. 63/750,817, filed on Jan. 29, 2025.
(60) Provisional application No. 63/720,216, filed on Nov. 14, 2024.
(60) Provisional application No. 63/714,353, filed on Oct. 31, 2024.

(51) Int. Cl. G02B 6/43; G02B 6/42

(52) U.S. Cl. CPC G02B 6/43; G02B 6/4206; G02B 6/4214; G02B 6/4274; G02B 6/4298

(57) ABSTRACT

A photonic wafer-scale interposer (PWSI) is accessed. The PWSI includes a plurality of waveguides. A front side of the PWSI is bonded to at least two switching chiplets. The at least two switching chiplets are coupled. The coupling is based on one or more waveguides in the plurality of waveguides. A data request is received by a first switching chiplet within the at least two switching chiplets, from a sending node within an external network. The data request requires switching between one or more nodes within the external network. The data request is switched, by the first switching chiplet, to a second switching chiplet in the at least two switching chiplets. The switching is based on the coupling. The data request is transferred, by the second switching chiplet, to a receiving node within the external network.

### RELATED APPLICATIONS

This application claims the benefit of U.S. provisional applications “Chiplet-Based Optical Wafer-Scale Network Switch” Ser. No. 63/750,817, filed January 29, 2025, and “Wafer-Scale Integration Power Delivery With An Isotropic Conductive Adhesive” Ser. No. 63/750,822, filed January 29, 2025.

This application is also a continuation-in-part of U.S. patent application “Back Side Power Delivery With An Anisotropic Conductive Film” Ser. No. 19/387,789, filed November 13, 2025, which claims the benefit of U.S. provisional applications “Back Side Wafer-Scale Power Delivery With An Anisotropic Film” Ser. No. 63/720,216, filed November 14, 2024, “Chiplet-Based Optical Wafer-Scale Network Switch” Ser. No. 63/750,817, filed January 29, 2025, and “Wafer-Scale Integration Power Delivery With An Isotropic Conductive Adhesive” Ser. No. 63/750,822, filed January 29, 2025.

The U.S. patent application “Back Side Power Delivery With An Anisotropic Conductive Film” Ser. No. 19/387,789, filed November 13, 2025, is also a continuation-in-part of U.S. patent application “Back Side Power Delivery For Wafer-Scale Integration With An Isometric Grid Compression Plate” Ser. No. 19/056,456, filed February 18, 2025, which claims the benefit of U.S. provisional patent applications “Chiplet-Based Optical Wafer-Scale Network Switch” Ser. No. 63/750,817, filed January 29, 2025, and “Wafer-Scale Integration Power Delivery With An Isotropic Conductive Adhesive” Ser. No. 63/750,822, filed January 29, 2025.

The U.S. patent application “Back Side Power Delivery For Wafer-Scale Integration With An Isometric Grid Compression Plate” Ser. No. 19/056,456, filed February 18, 2025 is also a continuation-in-part of U.S. patent application “Back Side Power Delivery For Wafer-Scale Integration With Solderless Modular Power Substrates” Ser. No. 19/023,647, filed January 16, 2025, which claims the benefit of U.S. provisional patent applications “Cooling for Wafer-Scale Integration With Back Side Power Coupling” Ser. No. 63/714,353, filed October 31, 2024, and “Back Side Wafer-Scale Power Delivery With An Anisotropic Film” Ser No. 63/720,216, filed November 14, 2024.

The U.S. patent application “Back Side Power Delivery For Wafer-Scale Integration With Solderless Modular Power Substrates” Ser. No. 19/023,647, filed January 16,

2025 is also a continuation-in-part of U.S. patent application “Wafer-Scale Integration With A Stiffening Isometric Grid Array” Ser. No. 18/978,188, filed December 12, 2024, which claims the benefit of U.S. provisional patent applications “Cooling for Wafer-Scale Integration With Back Side Power Coupling” Ser. No. 63/714,353, filed October 31, 2024, and “Back Side Wafer-Scale Power Delivery With An Anisotropic Film” Ser. No. 63/720,216, filed November 14, 2024.

The U.S. patent application “Wafer-Scale Integration With A Stiffening Isometric Grid Array” Ser. No. 18/978,188, filed December 12, 2024 is also a continuation-in-part of U.S. patent application “Cold Plate Cooling For Wafer-Scale Integration With Back Side Modular Power Delivery” Ser No. 18/958,107, filed November 25, 2024, which claims the benefit of U.S. provisional patent applications “Cooling for Wafer-Scale Integration With Back Side Power Coupling” Ser. No. 63/714,353, filed October 31, 2024, and “Back Side Wafer-Scale Power Delivery With An Anisotropic Film” Ser No. 63/720,216, filed November 14, 2024.

The U.S. patent application “Cold Plate Cooling For Wafer-Scale Integration With Back Side Modular Power Delivery” Ser No. 18/958,107, filed November 25, 2024, is also a continuation-in-part of U.S. patent application “Back Side Wafer-Scale Integration With Modular Power Delivery” Ser. No. 18/940,944, filed November 8, 2024, which claims the benefit of U.S. provisional patent application “Cooling for Wafer-Scale Integration With Back Side Power Coupling” Ser. No. 63/714,353, filed October 31, 2024.

Each of the foregoing applications is hereby incorporated by reference in its entirety.

### FIELD OF ART

This application relates generally to switching and more particularly to a chiplet-based optical wafer-scale network switch.

### BACKGROUND

Movement is an important component of life as we know it. Movement encompasses a huge variety of elements both physical and metaphysical. Physical elements, such as wheat harvested from a farm, must be moved from the farm to a processing facility to an end product facility to a wholesaler to a retailer to an end consumer, to name just one possible movement path for a physical element. Ideas also must undergo movement in order to be useful. Ideas from a human mind can be converted into written words, which can be converted into digital information, which can be converted into type on a screen, which can be consumed by one or even a billion or more other humans. And even though some science fiction writers have posited some kind of direct “mind meld” between beings, in reality, the movement of ideas, and even more so, physical elements, is a critical element of society in general and our current existence as humans in particular.

The flow control of such movements is a topic of great concern to governments, industries, and individuals. In fact, flow control is critical to many aspects of modern life. Whether the control of flow is designed for liquids, materials, vehicles, people, or information, flow control is essential to safety, efficiency, and security. Control of municipal water systems is essential to ensure a reliable supply of safe, potable water to residential, community, and industrial users. The municipal water supply is also critical to public safety by providing reliable water for fire suppression. Air traffic control directs and monitors the flow of air traffic to ensure safe and reliable air travel for civilian, commercial, or governmental purposes. Without such flow control systems, water safety would be unassured, air travel would be inefficient and dangerous, and firefighters would be left looking for ponds and streams as water sources for fighting fires.

The control of the flow of information is a hotly contested topic globally. While some countries enshrine a right to free speech, others suppress free speech through legal, electronic, and military means. Government crackdowns of protestors demanding free speech can range from blocking cellular networks and blocking internet access to armed attacks on protestors. The control of information can also be selective. Governments can limit access to news to only government approved sources. Network providers can identify and limit access to conspiracy theories and misinformation or not. Whatever the context, flow control directly impacts people’s lives.

An often overlooked application of flow control is that of the electronics industry. Information, when represented electronically, must flow from source to sink in order to be useful. When information is stored, the source, such as a spreadsheet, an article, or an image on film, must first be digitized before it can be stored electronically. A suitable storage facility must be obtained, and then a conduit from the digitized source to the storage facility established.

When information is downloaded, its digitized representation must be channeled to the desired sink, such as when a website cooking recipe is downloaded from the Internet and passed to a printer. Such conduits, channels, and networks all have limited ability to transmit or carry the data involved, therefore flow limitations must be accounted for. The demands on digital information flow in the modern electronics era are even greater. In fact, as processing speeds increase, information flow must also increase, lest the performance advantages of the higher processing speeds be rendered moot by an information flow bandwidth constraint. No matter what the digital application is, information flow must be managed to achieve the best performance.

### SUMMARY

Computer users of all stripes demand ever-faster computational resources in order to handle the enormous processing requirements of modern applications. These applications include video and image processing, audio processing, and natural language processing, among many others that have come to rely on techniques such as machine learning. As interest in such processing continues to increase, the goal of exascale computing has come to the fore. Exascale computing, which includes one quintillion (10¹⁸) computations per second, has been stymied in part by limitations of switching technologies. The switching transfers data requests and replies among processes executing on processors. The transfer of data among processors can be a significant challenge in the design of modern computer systems. For example, in current generative artificial intelligence (AI) systems, humongous amounts of data are needed for proper model training. A switching bottleneck often occurs because of the many processes demanding large datasets for such training models. Once trained, the models process even larger datasets to classify the data, determine inferences about the data, and so on. Faster switching enables faster data transfer and reduced risks of data transfer bottlenecks.

Disclosed techniques enable a chiplet-based optical wafer-scale network switch. A photonic wafer-scale interposer (PWSI) is accessed. The PWSI includes a plurality of waveguides. The waveguides can be within the PWSI. A front side of the PWSI is bonded to at least two switching chiplets. The front side of the PWSI can also be bonded to other elements that can include processor chips, accelerator chips, memory chips, and so on. The PWSI may include a plurality of through-silicon vias (TSVs). The at least two switching chiplets are coupled. The coupling is based on one or more waveguides in the plurality of waveguides. A first switching chiplet within the at least two switching chiplets receives a data request from a sending node within an external network. The data request requires switching between two or more nodes within the external network. The external network can include a local area network, a wide area network, and so on. The data request is switched by the first switching chiplet to a second switching chiplet in the at least two switching chiplets. The switching is based on the coupling. The data request is transferred by the second switching chiplet to a receiving node within the external network.

A method for switching is disclosed comprising: accessing a photonic wafer-scale interposer (PWSI), wherein the PWSI includes a plurality of waveguides, and wherein a front side of the PWSI is bonded to at least two switching chiplets; coupling the at least two switching chiplets, wherein the coupling is based on one or more waveguides in the plurality of waveguides; receiving, by a first switching chiplet within the at least two switching chiplets, from a sending node within an external network, a data request, wherein the data request requires switching between two or more nodes within the external network; switching the data request, by the first switching chiplet, to a second switching chiplet in the at least two switching chiplets, wherein the switching is based on the coupling; and transferring the data request, by the second switching chiplet, to a receiving node within the external network. In embodiments, the at least two switching chiplets include a serial interface. Some embodiments comprise converting a first serialized electrical data from the serial interface to serialized optical data. In embodiments, the converting is based on an electrical-to-optical (E/O) conversion. In embodiments, the E/O conversion occurs within the PWSI. In embodiments, the switching includes reconverting the serialized optical data to a second serialized electrical data. In embodiments, the reconverting is based on an optical-to electrical (O/E) conversion. In embodiments, the O/E conversion occurs within the PWSI.

An apparatus for switching is disclosed comprising: a photonic wafer-scale interposer (PWSI), wherein the PWSI includes a plurality of waveguides, and wherein a front side of the PWSI is bonded to at least two switching chiplets; a first switching chiplet within the at least two switching chiplets, wherein the first switching chiplet is coupled to a first optical emitter; a second switching chiplet within the at least two switching chiplets; an optical coupler, wherein the optical coupler couples light from the first optical emitter to a first waveguide within the plurality of waveguides; and a photodiode, wherein the photodiode couples light from the first waveguide to the second switching chiplet.

A system for switching is disclosed comprising: a photonic wafer-scale interposer (PWSI), wherein the PWSI includes a plurality of waveguides, and wherein a front side of the PWSI is bonded to at least two switching chiplets; a first switching chiplet within the at least two switching chiplets, wherein the first switching chiplet is coupled to a first optical emitter; a second switching chiplet within the at least two switching chiplets; an optical coupler, wherein the optical coupler couples light from the first optical emitter to a first waveguide within the plurality of waveguides; and a photodiode, wherein the photodiode couples light from the first waveguide to the second switching chiplet, wherein the system, when a data request from a sending node within an external network is sent to the first switching chiplet, is configured to: switch the data request to the second switching chiplet; and transfer the data request, by the second switching chiplet, to a receiving node within the external network.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for a chiplet-based optical wafer-scale network switch.

FIG. 2 is a flow diagram for coupling light.

FIG. 3 is an example of a waveguide cross-section in silicon-on-insulator (SOI) technology.

FIG. 4 is a first cross-section of a chiplet-based optical wafer-scale network switch apparatus.

FIG. 5 is a second cross-section of a PWSI and chiplets.

FIG. 6 is a system for a chiplet-based optical wafer-scale network switch apparatus.

FIG. 7 is an example of a HyperX network topology implemented with a PWSI.

### DETAILED DESCRIPTION

Techniques are disclosed for a chiplet-based optical wafer-scale network switch. Demand for significant processing performance improvements has soared, correlating with the development of new applications for processors, accelerators, and so on. This demand is placing immense pressure on designers to develop next-generation chips that can provide power to computers, servers, cloud servers, large language model (LLM) engines, etc. To meet these demands, vastly increased numbers of transistors have been added to chips such as systems-on-chip (SOCs). SOCs can include a wide range of circuitry which can include processors, memories, I/O circuits, and other elements. These SOCs can be dimensionally large, possessing tens of billions of transistors. Further, the immense increase of interest in and use of artificial intelligence (AI) applications, such as large neural networks, transformers, and so on, can require hundreds or even thousands of processing elements. The processing elements handle the perhaps trillions of computations demanded by the AI applications requiring the processing elements to request and to process many terabytes of data. These types of networks, whether built of SOCs, AI accelerators, or a combination of these and other chips, can be limited by switching bandwidth. That is, additional compute power from chips located in the same server rack, a different server rack, a different data center, and so on can be accessed within the network, but sending data where it needs to go can become the bottleneck to performance. In order to handle the immense numbers of requests and data replies, switching technology has also been studied to determine the causes of data transfer bottlenecks and to identify improvements to data switching techniques. However, switching capabilities continue to limit overall network processing performance. Disclosed embodiments address these performance limitations with a chiplet-based optical wafer-scale network switch.

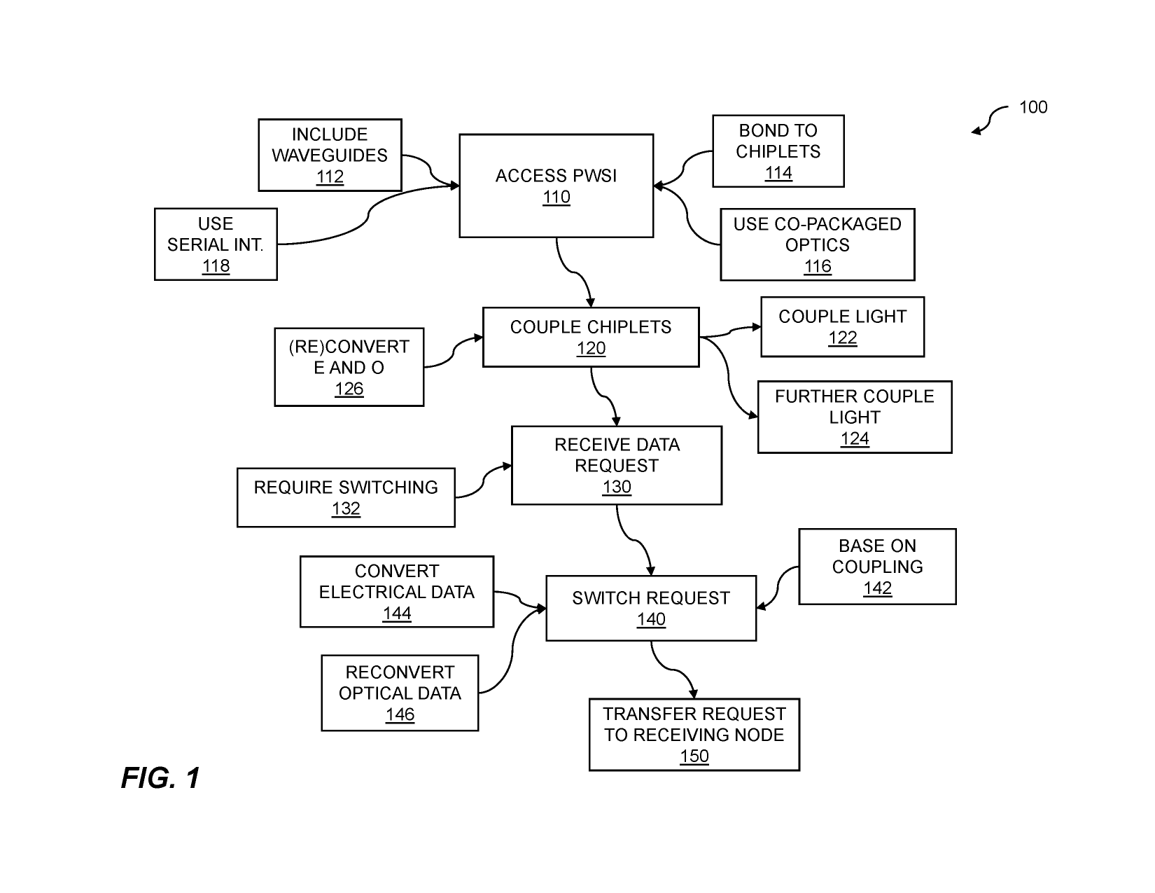

FIG. 1 is a flow diagram for a chiplet-based optical wafer-scale network switch. The flow 100 includes accessing a photonic wafer-scale interposer (PWSI) 110. Wafer-scale integration has been a long-sought goal of integrated circuit design and switching design. With wafer-scale integration, an entire wafer such as a silicon wafer could be used to fabricate one large network switch. However, since physical defects in the silicon wafer are distributed across the wafer, portions of circuitry which were fabricated over the defects would likely not function properly. In addition, errors that occur when fabricating the many layers that form the

PWSI further create portions of the PWSI that would likely not function. Instead, by attaching or bonding a plurality of switching chiplets to the PWSI, and forming waveguides within the PWSI, a wafer-scale network switch can be achieved. The PWSI can allow chips and chiplets from different manufacturing processes to be included. Further, wafer-level co-packaged optics can be mounted on the PWSI. Thus, the wafer forms the basis of the PWSI and can be used as an interposer to couple the switching chiplets and other elements. The wafer can be a 300 mm wafer, a 200 mm wafer, or a wafer of another size. The wafer can comprise silicon or another suitable material. In a usage example, another suitable material can include glass. The wafer can include any amount of front-end-of-line (FEOL) processing and/or back-end-of line (BEOL) processing. The processing can be based on Silicon on Insulator (SOI) or another process.

In the flow 100, the PWSI includes a plurality of waveguides 112. The waveguides can be built in a variety of technologies. In a usage example, a waveguide includes a silicon waveguide, fabricated on a silicon substrate, using a silicon-on-insulator fabrication technology. The waveguide can be used to switch data requests, received from a node within an external network, between switching chiplets (discussed below). In the flow 100, a front side of the PWSI is bonded to at least two switching chiplets 114. The switching chiplets can include chips designed for sending and receiving data, such as serial data. The serial data interface 118 can comprise a SERDES format, Universal Chiplet Interconnect Express (UCIe) format, or another serialized data format. The data can include electrical data and optical data. Other elements can be bonded to the front side of the PWSI. The other elements can include processors, memory, and so on. The other elements can include optical elements such as lasers which can be wafer-level co-packaged optics 116.

In exemplary implementations, the PWSI can comprise a monolithic wafer. The monolithic wafer can include a plurality of functional cores that are fabricated on the wafer. The functional cores can include one or more processors, AI accelerators, ASICS, peripheral interfaces, and so on. The functional cores can include memory. Other memory elements, such as SRAM, can be included in the monolithic wafer. The memory elements can also be fabricated on the wafer. Interconnect can be included on the monolithic wafer to couple any number of the functional cores, memory elements, and so on. The interconnect can comprise any number of metal layers on the wafer.

The flow 100 includes coupling 120 the at least two switching chiplets, wherein the coupling is based on one or more waveguides in the plurality of waveguides. The one or more waveguides can be used to switch a data request, a data reply, and so on. A data reply can include an amount of requested data. In embodiments, the coupling is based on a network topology. A network topology can include a ring topology, a star topology, a dragonfly topology, and so on. In embodiments, the network topology includes a HyperX^{®} topology. In embodiments, the first switching chiplet includes an optical emitter. The optical emitter can include a laser, a light emitting diode (LED), and so on. The first switching chiplet can further include an optical receiver. The optical receiver can include a photodiode. In the flow 100, the coupling includes coupling light 122, by a first optical coupler, from the optical emitter to a waveguide in the plurality of waveguides. The coupling the light can be accomplished using a variety of techniques. In embodiments, the first optical coupler includes an off-axis diffractive lens. The off-axis diffractive lens, which can bend light significantly off-axis, can bend the light from the emitter to enter the waveguide.

In another embodiment, the first optical coupler includes a mirror. The mirror can be fabricated within the PWSI. In further embodiments, the first optical coupler includes a bent waveguide. The bent waveguide can be fabricated within the PWSI. The bent waveguide can enable transfer of light from the emitter associated with the first switching chiplet into the waveguide using the same materials as the waveguide. The flow 100 further includes coupling light, by a second optical coupler 124, from the waveguide to an optical receiver on the second switching chiplet. A variety of techniques can be used to implement the second switching chiplet. In embodiments, light from the waveguide is coupled to the second switching chiplet by a photodiode, wherein the photodiode is within the PWSI. The coupling can include an electrical (E) to optical (O) conversion and then an optical (O) to electrical (E) reconversion 126. In embodiments, the at least two switching chiplets include a serial interface. Some embodiments comprise converting a first serialized electrical data from the serial interface to serialized optical data. In embodiments, the converting is based on an electrical-to-optical (E/O) conversion. In embodiments, the E/O conversion occurs within the PWSI. In embodiments, the switching includes reconverting the serialized optical data to a second serialized electrical data. In embodiments, the reconverting is based on an optical-to electrical (O/E) conversion. In embodiments, wherein the O/E conversion occurs within the PWSI. In embodiments, the coupling and the switching are based on wafer-level co-packaged optics.

The flow 100 includes receiving 130, by a first switching chiplet within the at least two switching chiplets, from a sending node within an external network, a data request. The data request can be received over a network. The network can include a local area network, a wide area network, and so on. The network can include a network-on-chip (NOC). In the flow 100, the data request requires switching 132 between two or more nodes within the external network. The switching between the two or more nodes within the external network can be accomplished by switching between the first switching chiplet and the second switching chiplet via a waveguide within the PWSI. The flow 100 includes switching the data request 140, by the first switching chiplet, to a second switching chiplet in the at least two switching chiplets, wherein the switching is based on the coupling 142. The switching between the first switching chiplet and the second switching chiplet can use a waveguide in the plurality of waveguides within the PWSI. In embodiments, the at least two switching chiplets include a serial interface. The serial interface can include an optical emitter and an optical receiver. The optical emitter can include a laser, an LED, or another suitable solid state light emitting source. In embodiments, the optical receiver can include a photodiode.

The flow 100 further includes converting a first serialized electrical data 144 from the serial interface to serialized optical data, wherein the converting is based on an electrical-to-optical (E/O) conversion, wherein the E/O conversion occurs within the PWSI. Data from an external network can be received in electrical form. The data from the external network can include serialized electrical data. The serialized electrical data can be converted to serialized optical data by a laser diode, an LED, and the like. The E/O device can be bonded to the PWSI, within the PWSI, etc. In embodiments, the coupling and the switching are based on wafer-level co-packaged optics. The co-packaged optics can include light sources such as lasers and LEDs, lenses, photodetectors, and so on. In the flow 100, the switching includes reconverting 146 the serialized optical data to a second serialized electrical data, wherein the reconverting is based on an optical-to electrical (O/E) conversion, wherein the O/E conversion occurs within the PWSI. The O/E conversion can be accomplished using a photodetector element such as a photodiode.

The flow 100 includes transferring the data request 150, by the second switching chiplet, to a receiving node within the external network. The receiving node can receive the data request and can respond to the data request by sending data to the sending node. The data can include video or image data, audio data, alphanumeric data, and so on. The data that is sent can be sent back through the PWSI to the sending node in the external network.

Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors.

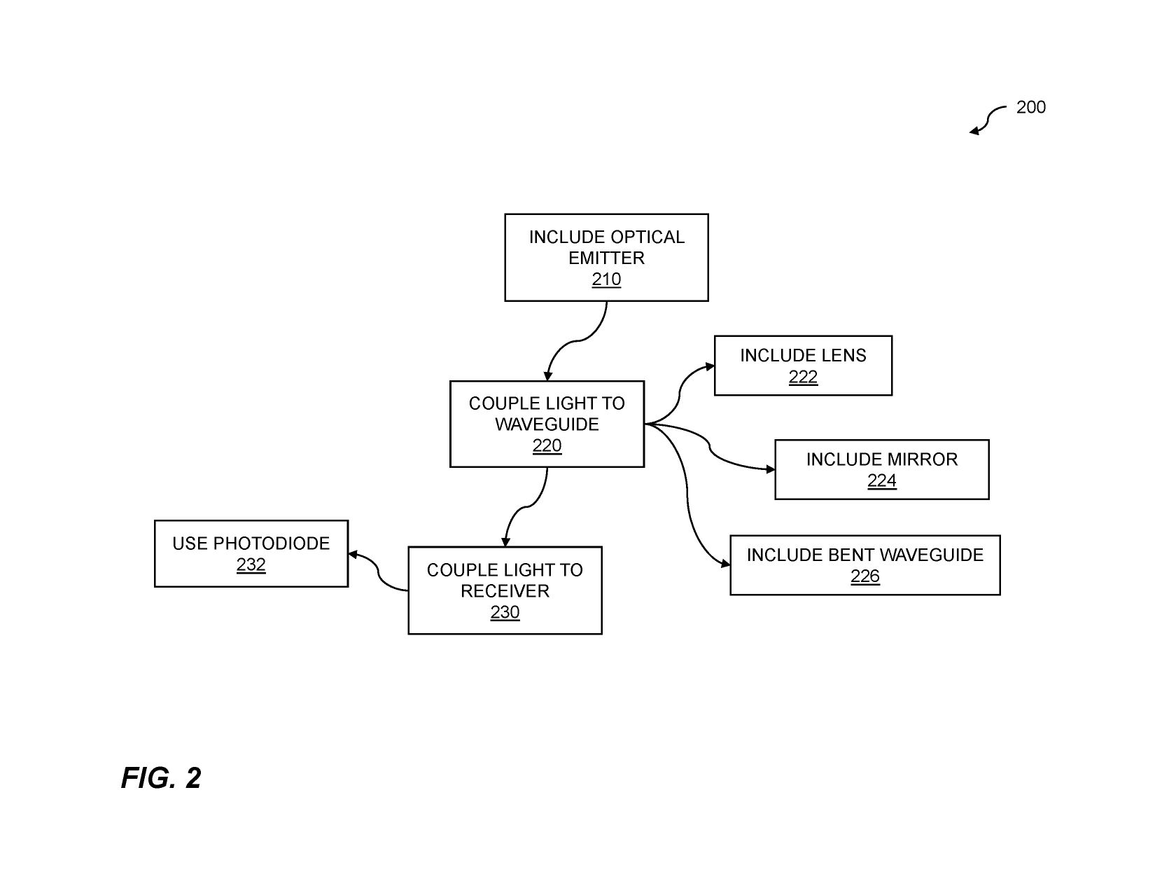

FIG. 2 is a flow diagram for coupling light. Light coupling can enable a chiplet-based optical wafer-scale network switch. A photonic wafer-scale interposer (PWSI) is accessed. The PWSI includes a plurality of waveguides. The waveguides can be within the PWSI. A front side of the PWSI is bonded to at least two switching chiplets. The front side of the PWSI can also be bonded to other elements that can include processor chips, accelerator chips, memory chips, and so on. The PWSI may include a plurality of through-silicon vias (TSVs). The at least two switching chiplets are coupled. The coupling is based on one or more waveguides in the plurality of waveguides.

The flow 200 includes including an optical emitter 210 in the first switching chiplet. Various types of optical emitters can be employed, such as a laser, a light emitting diode (LED), and so on. The optical emitter can transform electrical (E) signals from a source to optical (O) signals to be routed through the PWSI. The flow 200 includes coupling light to a waveguide 220 included among the plurality of waveguides on the PWSI. The coupling the light can be accomplished using a variety of techniques. The coupling can include a lens 222. Various suitable lenses can be used. In embodiments, the first optical coupler includes an off-axis diffractive lens. The off-axis diffractive lens, which can bend light significantly off-axis, can bend the light from the emitter to enter the waveguide at a suitable angle. The coupling can include a mirror 224. The mirror can be fabricated within the PWSI. The coupling can include a bent waveguide 226. The bent waveguide can be fabricated within the PWSI. The bent waveguide can enable transfer of light from the emitter associated with the first switching chiplet into the waveguide using the same materials as the waveguide.

The flow 200 includes coupling light from the waveguide to a receiver 230. The coupling can be performed by a second optical coupler, from the waveguide to an optical receiver on the second switching chiplet. A variety of techniques can be used to implement the second switching chiplet. Light from the waveguide can be coupled to the second switching chiplet by using a photodiode 232. The photodiode can be embedded, or co-packaged, within the PWSI. Thus, the coupling can include an electrical (E) to optical (O) conversion at the first switching chiplet, and then an optical (O) to electrical (E) reconversion at the second switching chiplet. In embodiments, the first switching chiplet includes an optical emitter. In embodiments, the coupling includes coupling light, by a first optical coupler, from the optical emitter to a waveguide in the plurality of waveguides. In embodiments, the first optical coupler includes an off-axis diffractive lens. In embodiments, the first optical coupler includes a mirror. In embodiments, the first optical coupler includes a bent waveguide. Some embodiments comprise further coupling light, by a second optical coupler, from the waveguide to an optical receiver on the second switching chiplet. In embodiments, light from the waveguide is coupled to the second switching chiplet by a photodiode. In embodiments, the photodiode is within the PWSI.

Various steps in the flow 200 may be changed in order, repeated, omitted, or the like without departing from the disclosed concepts. Various embodiments of the flow 200 can be included in a computer program product embodied in a non-transitory computer readable medium that includes code executable by one or more processors.

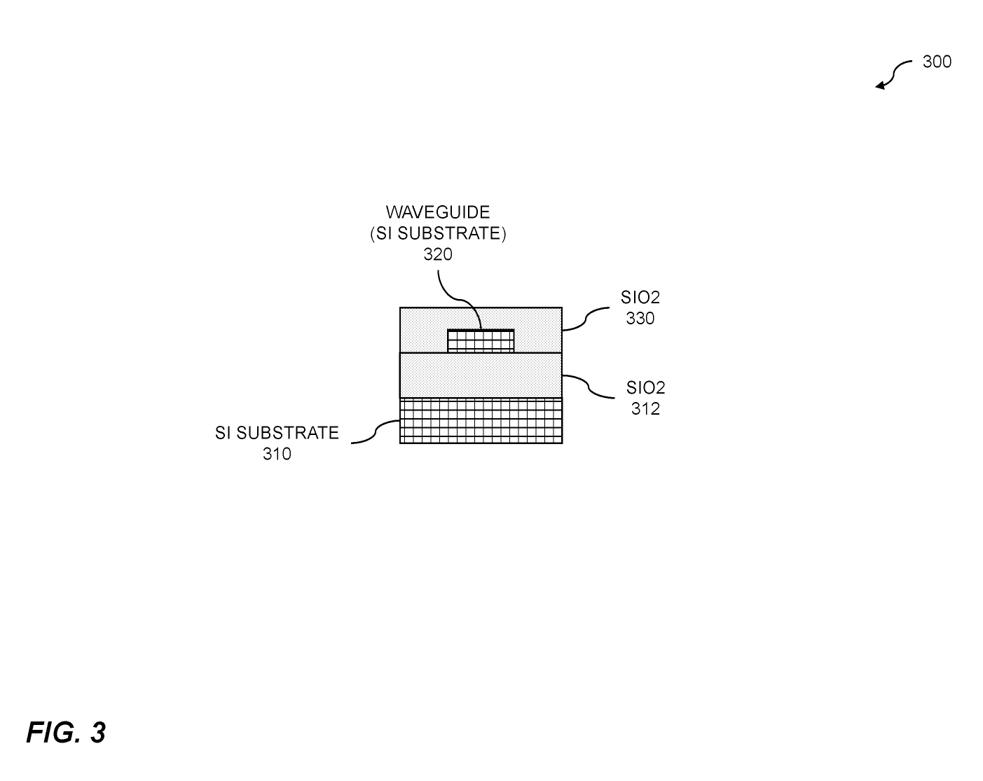

FIG. 3 is an example of a waveguide cross-section in silicon-on-insulator (SOI) technology. A waveguide cross-section in silicon-on-insulator technology can enable a chiplet-based optical wafer-scale network switch. A photonic wafer-scale interposer (PWSI) is accessed. The PWSI includes a plurality of waveguides. The waveguides can be within the PWSI. A front side of the PWSI is bonded to at least two switching chiplets. The front side of the PWSI can also be bonded to other elements that can include processor chips, accelerator chips, memory chips, and so on. The PWSI may include a plurality of through-silicon vias (TSVs). The at least two switching chiplets are coupled. The coupling is based on one or more waveguides in the plurality of waveguides. A waveguide can be used to transfer a signal such as an optical signal between two elements associated with a switch such as a data switch. The waveguide can be fabricated within a monolithic wafer which includes one or more functional chips. The waveguide can be fabricated within a photonic wafer-scale interposer (PWSI), where the PWSI can be based on a wafer such as a silicon wafer, a glass wafer, and so on. The wafer can be used as a substrate for the PWSI. A plurality of waveguides can be fabricated within the PWSI in order to enable switching between a plurality of switching elements such as switching chiplets. The chiplets can be associated with a switch such as a network switch. The plurality of waveguides enables a chiplet-based optical wafer-scale network switch.

The cross-section of an example waveguide fabricated in a silicon-on-insulator (SOI) technology is shown 300. A silicon substrate 310 is obtained. The silicon substrate can include a silicon wafer, where the silicon wafer can include a 200 mm silicon wafer, a 300 mm silicon wafer, and so on. A silicon dioxide (insulator) layer 312 can be grown, deposited, or otherwise formed on the silicon wafer. One or more waveguides, such as waveguide 320, can be formed on the insulator layer 312. An additional insulator layer 330 can be placed over the one or more waveguides. The insulator layer can be planarized in order to enable fabrication of further elements. The waveguide can conduct light in order to establish optical communications between an optical source and an optical receiver within the PWSI.

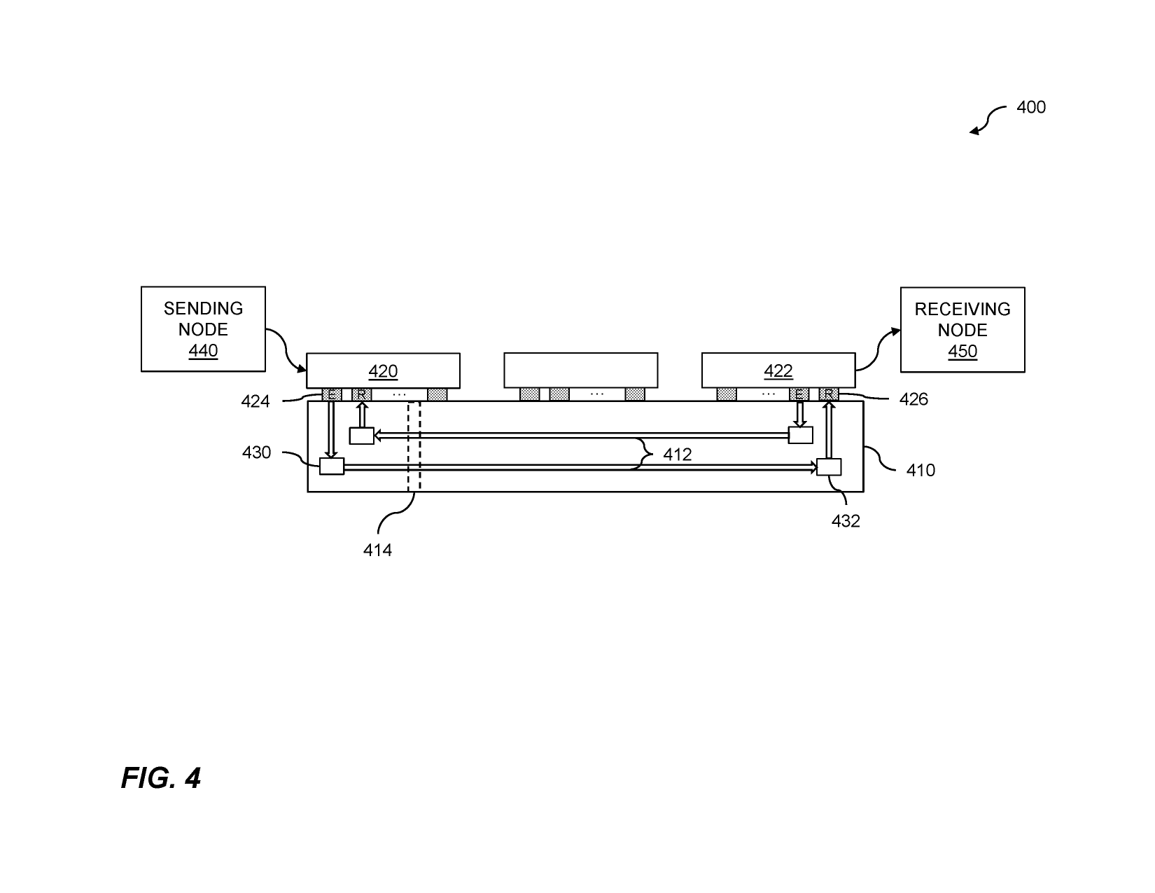

FIG. 4 is a first cross-section of a chiplet-based optical wafer-scale network switch apparatus. A photonic wafer-scale interposer (PWSI) is accessed. The PWSI includes a plurality of waveguides. The waveguides can be within the PWSI. A front side of the PWSI is bonded to at least two switching chiplets. The front side of the PWSI can also be bonded to other elements that can include processor chips, accelerator chips, memory chips, and so on. The PWSI may include a plurality of through-silicon vias (TSVs). The at least two switching chiplets are coupled. The coupling is based on one or more waveguides in the plurality of waveguides. The apparatus can receive a data request from a sending node within an external network. The apparatus can switch the data request from a first switching chiplet associated with the apparatus to a second switching chiplet associated with the apparatus. The second switching chiplet can transfer the data request to a receiving node. The apparatus enables a chiplet-based optical wafer-scale network switch. Disclosed is an apparatus for switching comprising: a photonic wafer-scale interposer (PWSI), wherein the PWSI includes a plurality of waveguides, and wherein a front side of the PWSI is bonded to at least two switching chiplets; a first switching chiplet within the at least two switching chiplets, wherein the first switching chiplet is coupled to a first optical emitter; a second switching chiplet within the at least two switching chiplets; an optical coupler, wherein the optical coupler couples light from the first optical emitter to a first waveguide within the plurality of waveguides; and a photodiode, wherein the photodiode couples light from the first waveguide to the second switching chiplet.

The apparatus 400 includes a photonic wafer-scale interposer (PWSI) 410. The PWSI can include a wafer such as a silicon wafer, a glass wafer, and so on. The PWSI includes a plurality of waveguides. Two example waveguides 412 are shown. The waveguides are within the PWSI. The waveguides can span multiple chiplets across a substantial portion of the PWSI, thus the waveguides can be manufactured using a waveguide reticle stitching process. The PWSI can further include through-silicon vias (TSVs) such as TSV 414. The TSV can couple other electronics via the back side of the PWSI. A front side of the PWSI is bonded to at least two switching chiplets. The switching chiplets can include switching chiplet 420 and switching chiplet 422. Each switching chiplet includes at least one emitter such as emitter 424 and at least one receiver such as receiver 426. The emitter and the receiver can include electrical elements (described below), optical elements, HyperX elements, and so on. The apparatus includes a first switching chiplet 420 within the at least two switching chiplets, wherein the first switching chiplet is coupled to a first optical emitter 424. The first optical emitter can emit optical data, which can be serialized optical data. The apparatus includes a second switching chiplet 422 within the at least two switching chiplets. The second switching chiplet is coupled to an optical receiver 426. The optical receiver can receive an optical signal from the optical emitter via a waveguide. The apparatus includes an optical coupler 430, wherein the optical coupler couples light from the first optical emitter to a first waveguide within the plurality of waveguides. Discussed previously and throughout, various techniques can be used to accomplish the optical coupling. The first optical coupler can include an off-axis diffractive lens, a mirror, a bent waveguide, etc. The apparatus includes a photodiode 432, wherein the photodiode couples light from the first waveguide to the second switching chiplet.

The first switching chiplet within the at least two switching chiplets receives a data request from a sending node within an external network. The sending request is sent by a sending node such as sending node 440. The first switching chiplet switches the data request to a second switching chiplet in the at least two switching chiplets. The switching is based on the coupling of the at least two switching chiplets. The coupling is based on one or more waveguides in the plurality of waveguides. The coupling includes the emitter 424, the coupler 430, the photodiode 432, and the receiver 426. The data request switched to the second switching chiplet by the first switching chiplet is transferred to a receiving node such as receiving node 450 within the external network. The transferring is accomplished by the second switching chiplet.

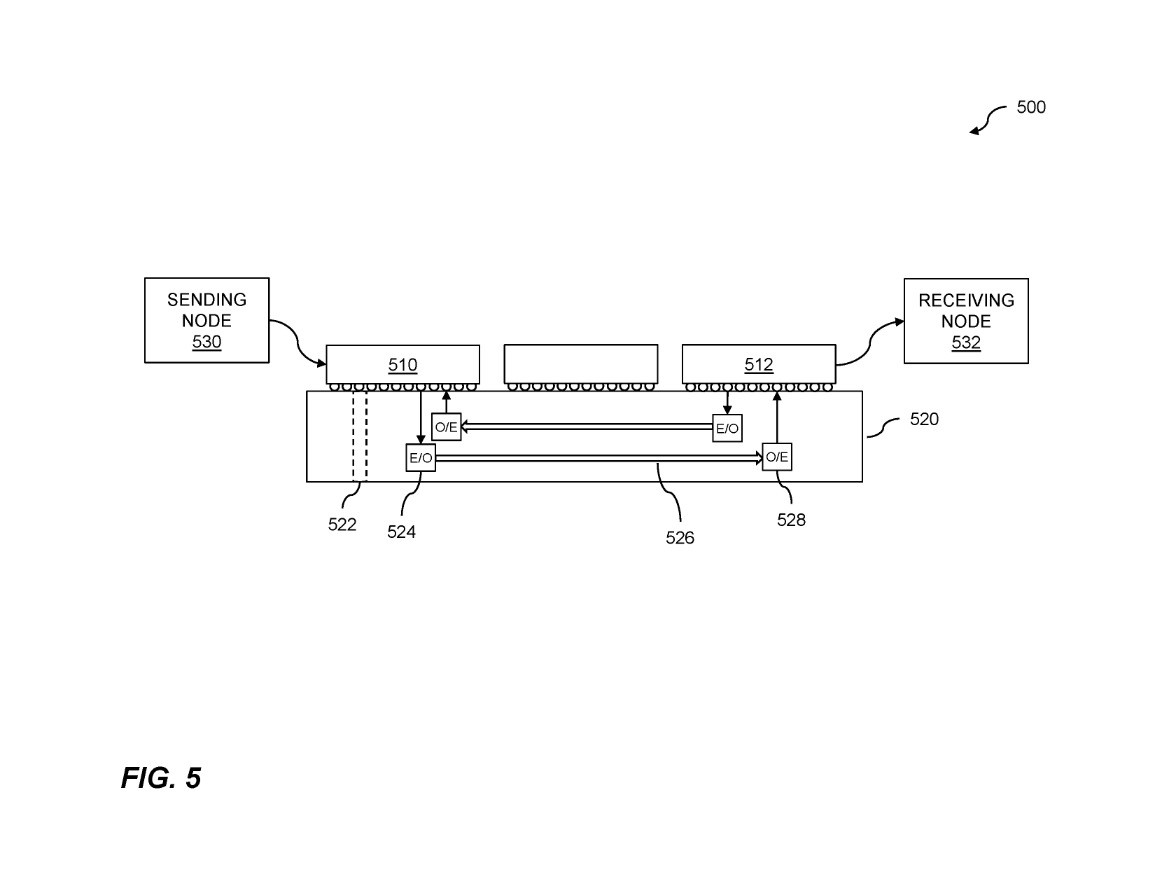

FIG. 5 is a second cross-section of a PWSI and chiplets. A photonic wafer-scale interposer (PWSI) is accessed. The PWSI includes a plurality of waveguides. The waveguides can be within the PWSI. A front side of the PWSI is bonded to at least two switching chiplets. The front side of the PWSI can also be bonded to other elements that can include processor chips, accelerator chips, memory chips, and so on. The PWSI may include a plurality of through-silicon vias (TSVs). The at least two switching chiplets are coupled. The coupling is based on one or more waveguides in the plurality of waveguides.

The photonic wafer-scale interposer (PWSI) 500 includes a plurality of waveguides. A front side of the PWSI is bonded to at least two switching chiplets. The PWSI enables a chiplet-based optical wafer-scale network switch. At least two switching chiplets such as switching chiplet 510 and switching chiplet 512 are bonded to the front side of the PWSI 520. The chiplets can be bonded to the PWSI via micro-bumps, controlled collapse chip connections (C4s), and so on. The PWSI can include a plurality of through-silicon vias (TSVs) such as TSV 522. A TSV can include an electrical connection that completely passes through a wafer such as a silicon wafer, a glass wafer, or a die. The plurality of TSVs, if present, can be oriented vertically in order to enable connections between the front side of the wafer and the back side of the wafer. The switching chiplet 510 can switch a data request received from a sending node such as sending node 530 to the second switching chiplet 512. The second switching chiplet can transfer the data request to a receiving node such as receiving node 532.

The switching by the first switching chiplet of the data request to the second switching chiplet can be accomplished by converting electrical data, which can be serialized electrical data, to optical data and reconverting the optical data to electrical data. Embodiments include converting a first serialized electrical data from the serial interface to serialized optical data, wherein the converting is based on an electrical-to-optical (E/O) conversion, wherein the E/O conversion occurs within the PWSI. The E/O conversion can be accomplished by an E/O converter 524. The E/O converter is coupled to waveguide 526 within the plurality of waveguides. The waveguide can transfer the optical signals from the E/O converter to an optical-to-electrical (O/E) converter 528. In embodiments, the switching includes reconverting the serialized optical data to a second serialized electrical data, wherein the reconverting is based on an optical-to electrical (O/E) conversion, wherein the O/E conversion occurs within the PWSI.

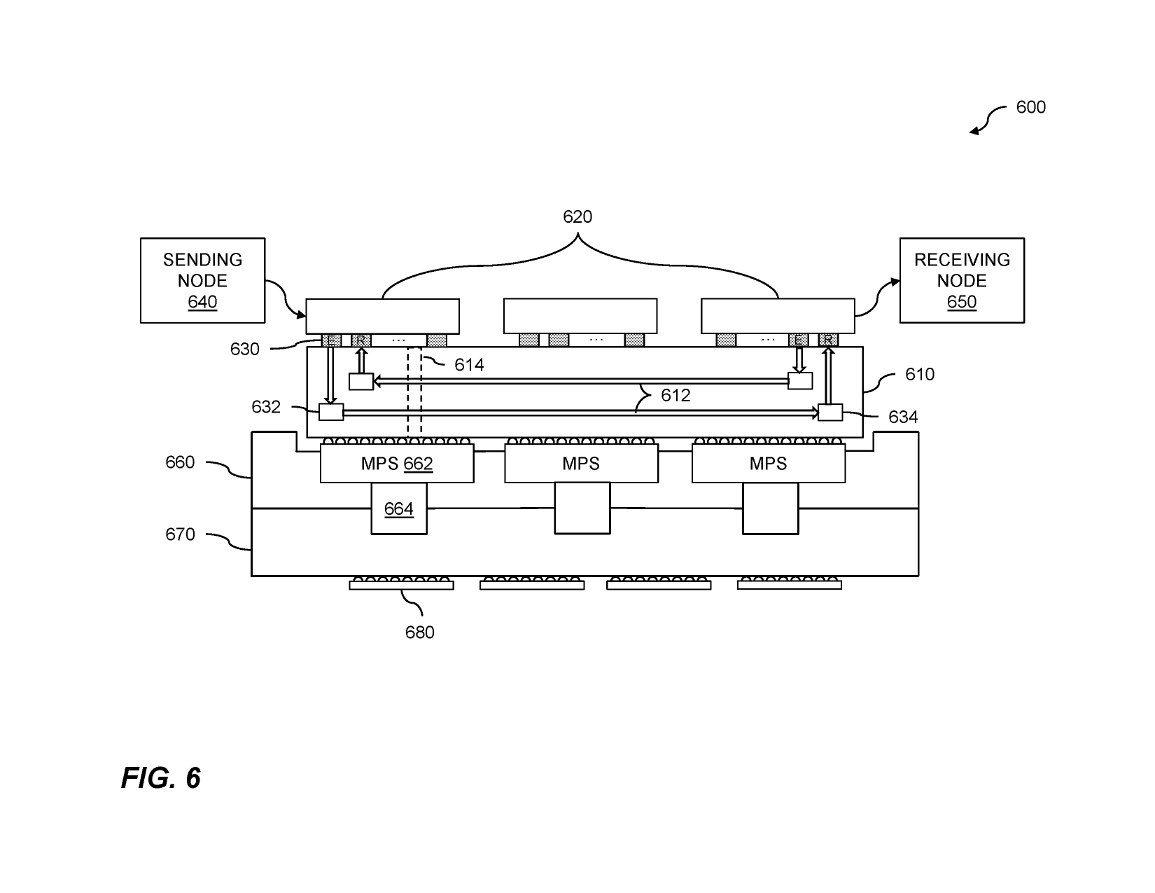

FIG. 6 is a system for a chiplet-based optical wafer-scale network switch apparatus. A photonic wafer-scale interposer (PWSI) is accessed. The PWSI includes a plurality of waveguides. The waveguides can be within the PWSI. A front side of the PWSI is bonded to at least two switching chiplets. The front side of the PWSI can also be bonded to other elements that can include processor chips, accelerator chips, memory chips, and so on. The PWSI may include a plurality of through-silicon vias (TSVs). The at least two switching chiplets are coupled. The coupling is based on one or more waveguides in the plurality of waveguides.

A wafer-scale network comprising waveguides and at least two switching chiplets bonded to a front side of a photonic wafer-scale interposer is used to transfer a data request between a sending node in an external network and a receiving node within the external network. The data request is switched from a first switching chiplet that received the data request from the sending node to a second switching chiplet. The second switching chiplet transfers the data request to the receiving node. The switching chiplets can be in communication with other elements bonded to or mounted to the PWSI. The other elements can include lasers, photo diodes, power supplies, processors, and so on. The communication with other elements can be accomplished using interconnect associated with the PWSI. The communication can further be accomplished using through-silicon vias (TSVs). To enable the fabrication of the TSVs and to improve the reliability of the TSVs, the PWSI can be ground, polished, and so on to reduce the thickness of the PWSI. The resulting thin PWSI can be delicate and therefore susceptible to cracking and fracturing. The PWSI can be reinforced or supported using a stiffening isometric grid array. The stiffening isometric grid array can provide stiffening to the PWSI to assist with protecting the PWSI from cracks and fractures.

Disclosed is a system for switching comprising: a photonic wafer-scale interposer (PWSI), wherein the PWSI includes a plurality of waveguides, and wherein a front side of the PWSI is bonded to at least two switching chiplets; a first switching chiplet within the at least two switching chiplets, wherein the first switching chiplet is coupled to a first optical emitter; a second switching chiplet within the at least two switching chiplets; an optical coupler, wherein the optical coupler couples light from the first optical emitter to a first waveguide within the plurality of waveguides; and a photodiode, wherein the photodiode couples light from the first waveguide to the second switching chiplet, wherein the system, when a data request from a sending node within an external network is sent to the first switching chiplet, is configured to: switch the data request to the second switching chiplet; and transfer the data request, by the second switching chiplet, to a receiving node within the external network.

The system 600 includes a photonic wafer-scale interposer (PWSI) 610, wherein the PWSI includes a plurality of waveguides 612, and wherein a front side of the PWSI is bonded to at least two switching chiplets 620. The PWSI can comprise an inorganic wafer such as a silicon wafer, a glass wafer, and so on. The PWSI can include an organic wafer. Additional elements such as processor chips, multiprocessor chips, graphics processor chips, application-specific integrated circuits (ASICs), systems-on-chip (SoCs), memory chips, artificial intelligence (AI) and machine learning (ML) accelerators, and so on can be bonded to or mounted on the PWSI. The waveguides can be fabricated using a variety of technologies. In embodiments, the waveguides are fabricated using a silicon-on-insulator (SOI) technology. Recall that electrical connections can be made from a front side of the PWSI to a back side of the PWSI. The connections from the front side of the PWSI to the back side of the PWSI can be accomplished using one or more through-silicon vias (TSVs) 614. The TSVs may be included for some implementations of the PWSI and may be omitted for other implementations of the PWSI.

The switching chiplets and other elements, if present, can create prodigious heat during operation. The heat can be due to current provided to the chiplets such as active current, overcurrent, leakage current, and so on. The heat can result from IR drops associated with interconnect, active devices, leakage current, etc. within the functional chips. The chiplets can be bonded to the PWSI via micro-bumps, controlled collapse chip connections (C4s), and so on. The PWSI may include a plurality of through-silicon vias (TSVs). A TSV can include an electrical connection that completely passes through a wafer such as a silicon wafer or a die. The plurality of TSVs, if present, can be oriented vertically in order to enable connections between the front side of the wafer and the back side of the wafer.

Discussed previously, each chiplet within the at least two switching chiplets is coupled to one or more waveguides in the plurality of waveguides. In embodiments, the first switching chiplet includes an optical emitter 630. The optical emitter can include a light emitting diode (LED), a laser, and so on. The optical emitter is coupled to a waveguide. In embodiments, the coupling includes coupling light, by a first optical coupler 632, from the optical emitter to a waveguide in the plurality of waveguides. The coupling can be accomplished using a variety of techniques. In embodiments, the first optical coupler includes an off-axis diffractive lens. In other embodiments, the first optical coupler includes a mirror. In further embodiments, the first optical coupler includes a bent waveguide. The off-axis diffractive lens, the mirror, and the bent waveguide can be fabricated using a variety of fabrication techniques.

Multiple options exist to couple the light to the receiver on the second switching chiplet. A second optical coupler can be coupled to a far end of a waveguide. Embodiments include further coupling light, by a second optical coupler 634, from the waveguide to an optical receiver on the second switching chiplet. The second optical coupler can be based on a variety of technologies. In embodiments, light from the waveguide is coupled to the second switching chiplet by a photodiode, wherein the photodiode is within the PWSI. Other suitable optical detectors can also be used. Other techniques can be used to transfer the request from the first switching chiplet to the second switching chiplet. In embodiments, the at least two switching chiplets include a serial interface. The serial interface can be based on electrical signals. Embodiments further include converting a first serialized electrical data from the serial interface to serialized optical data, wherein the converting is based on an electrical-to-optical (E/O) conversion, wherein the E/O conversion occurs within the PWSI. The optical signals can be converted back to electrical signals. In embodiments, the switching includes reconverting the serialized optical data to a second serialized electrical data, wherein the reconverting is based on an optical-to electrical (O/E) conversion, wherein the O/E conversion occurs within the PWSI.

Recall that a data request can be received from a sending node such as sending node 640. The data request can request a variety of data types such as image data, audio data, alphanumeric data, and so on. The data request that is received from the sending node can be switched by the first switching chiplet to a second switching chiplet. The second switching chiplet can transfer the data request to a receiving node such as receiving node 650. Both the sending node and the receiving node can include nodes in an external network.

The system 600 may include an isometric grid array (IGA) 660. The back side of the PWSI can be inserted into the IGA. The IGA, if present, can stiffen the PWSI. A cold plate (not shown) can then be attached to the IGA, thus pressing the cold plate to the functional chips on a front side of the PWSI. This in turn causes pressure on the PWSI toward the IGA. At the same time, the IGA presses toward the PWSI since it is attached to the cold plate. The attaching can be accomplished using one or more screws, clips, locking fasteners, and so on, thus stiffening the PWSI. The IGA can provide support for the PWSI by enhancing stability of the PWSI, stiffness of the PWSI, etc. Enhancing the stiffness of the PWSI can significantly reduce the risk of the PWSI cracking, even under its own weight. The IGA can comprise a grid. The IGA can maintain a coplanarity of the PWSI. By maintaining coplanarity of the PWSI, risks of cracking and fracturing the PWSI can be reduced. In addition, better electrical contacts can be made across the PWSI.

The system 600 may include a plurality of modular power substrates (MPSs), such as MPS 662. The MPSs can include one or more DC-to-DC converters, a high voltage socket such as 664, one or more rigid-flex strips, and so on. Each MPS within the plurality of MPSs can be based on a form factor mirroring one or more corresponding functional chiplets such as functional chiplets 620. The one or more MPSs can be attached to the back side of the WSI through the plurality of open recesses. Each open recess within the IGA can match a form factor of a corresponding MPS in the plurality of MPSs. The MPSs can be connected mechanically to a unified control board (UCB) 670. The UCB can include a plurality of DC-to-DC power converters 680. Power can be sent from the DC-to-DC power converters to the MPS, which can send DC power through the TSVs to the at least two switching chiplets bonded to the top of the PWSI. A first voltage conversion can be accomplished by the UCB. A second voltage conversion can be accomplished by the MPSs before being sent to the switching chiplets.

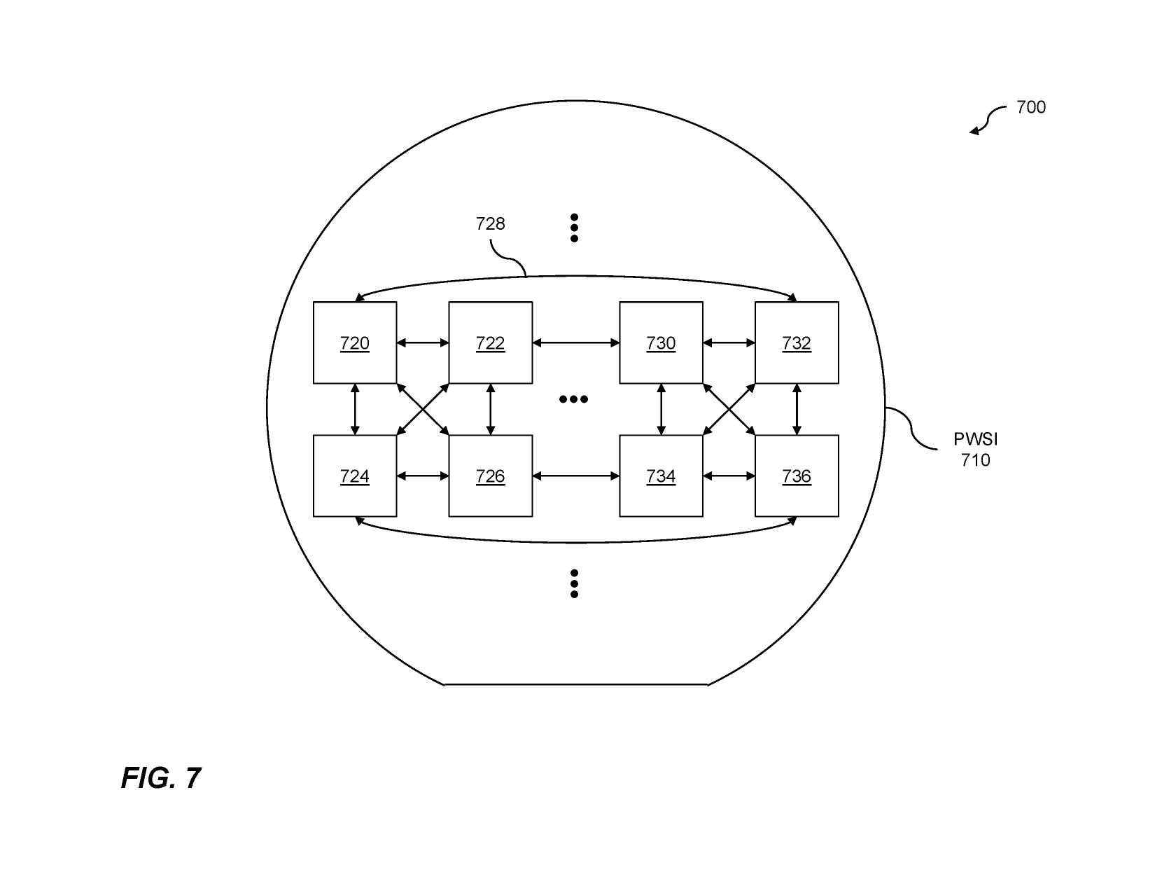

FIG. 7 is an example of a HyperX network topology implemented with a PWSI. A HyperX network topology implemented with a PWSI can be enabled by a chiplet-based optical wafer-scale network switch. A photonic wafer-scale interposer (PWSI) is accessed. The PWSI includes a plurality of waveguides. The waveguides can be within the PWSI. A front side of the PWSI is bonded to at least two switching chiplets. The front side of the PWSI can also be bonded to other elements that can include processor chips, accelerator chips, memory chips, and so on. The PWSI may include a plurality of through-silicon vias (TSVs). The at least two switching chiplets are coupled. The coupling is based on one or more waveguides in the plurality of waveguides. Discussed previously and throughout, a chiplet- based optical wafer-scale network switch can be used to accomplish high-speed data transfers between two or more nodes external to the wafer-scale network switch. The HyperX network topology offers significant improvements in comparison to other network technologies such as ring network topologies, star network topologies, mesh network topologies, and so on. The improvements by the HyperX network topology include scalability, ease of installation, redundancy, and fault tolerance, among other improvements. A HyperX network topology implemented with a photonic wafer-scale interposer (PWSI) is enabled by a chiplet-based optical wafer-scale network switch. A photonic wafer-scale interposer (PWSI) is accessed. The PWSI includes a plurality of waveguides. A front side of the PWSI is bonded to at least two switching chiplets. The at least two switching chiplets are coupled. The coupling is based on one or more waveguides in the plurality of waveguides. A data request is received, by a first switching chiplet within the at least two switching chiplets, from a sending node within an external network. The data request requires switching between two or more nodes within the external network. The data request is switched, by the first switching chiplet, to a second switching chiplet in the at least two switching chiplets. The switching is based on the coupling. The data request is transferred, by the second switching chiplet, to a receiving node within the external network.

A plurality of parameters associated with a HyperX network can be adjusted to benefit switching characteristics of the HyperX network. A HyperX network can enable high-radix switches. A high-radix switch such as a high-radix switching chiplet can enable a substantial number of connections per chiplet. Enabling the connections supports high-throughput data transfer. The HyperX network can scale efficiently. Efficient scaling of a network can enable processing of high data bandwidth applications such as machine learning applications. The HyperX network can enable adaptive routing. The adaptive routing can vary routing across the network as amounts of data traffic across the network vary over time. The HyperX network can enable a “low diameter” network. A low diameter network can enable data transfer between nodes of the HyperX network, such as data transfer between switching chiplets, with a low number of hops between nodes. A low number of hops (e.g., intermediate switching chiplets) between a source chiplet and a destination chiplet reduces network latency.

The figure shows an example HyperX network 700. The HyperX network is shown implemented on a photonic wafer-scale interposer (PWSI) 710. The PWSI can be based on one or more types of wafers such as a silicon (Si) wafer, a glass wafer, and so on. Recall that a front side of the PWSI can be bonded to at least two switching chiplets. The switching chiplets, which can include modular integrated circuits or chips, can include circuits designed for high-speed switching applications. The switching can be based on optical switching, electro-optical switching, etc. In the figure, two quads of elements are shown. The elements can include networking elements such as switches, routers, smart hubs, and so on. In embodiments, the elements comprise switching chiplets. The first quad of elements includes elements 720, 722, 724, and 726. The second quad of elements includes elements 730, 732, 734, and 736. While two quads of elements are shown, other groupings of switching chiplet elements can be implemented. Also, more than two groupings of the switching chiplets can be bonded to the PWSI. Interconnection is provided between and among the switching chiplets. The interconnections between the switching chiplets can be provided by the plurality of waveguides included in the PWSI. Further interconnection for connections such as power, control, and so on can be provided between the switching chiplets using metal (wire) interconnect. In addition to interconnections provided between “nearest neighbor” switching chiplets, interconnections can be provided between clusters of chiplets. An example interconnection 728 is shown between element (switching chiplet) 720 and element (switching chiplet) 732. These latter interconnections minimize the “diameter” of the HyperX network. The HyperX network implemented with a PWSI as shown can enable efficient use of multicore optical fiber interconnect which, in some non-PWSI implementations, must be connected to multiple switches within the network.

Each of the above methods may be executed on one or more processors on one or more computer systems. Embodiments may include various forms of distributed computing, client/server computing, and cloud-based computing. Further, it will be understood that the depicted steps or boxes contained in this disclosure’s flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagram and flow diagram illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system”— may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for switching comprising:
accessing a photonic wafer-scale interposer (PWSI), wherein the PWSI includes a plurality of waveguides, and wherein a front side of the PWSI is bonded to at least two switching chiplets;
coupling the at least two switching chiplets, wherein the coupling is based on one or more waveguides in the plurality of waveguides;
receiving, by a first switching chiplet within the at least two switching chiplets, from a sending node within an external network, a data request, wherein the data request requires switching between two or more nodes within the external network;
switching the data request, by the first switching chiplet, to a second switching chiplet in the at least two switching chiplets, wherein the switching is based on the coupling; and
transferring the data request, by the second switching chiplet, to a receiving node within the external network.

2. The method of claim 1 wherein the first switching chiplet includes an optical emitter.

3. The method of claim 2 wherein the coupling includes coupling light, by a first optical coupler, from the optical emitter to a waveguide in the plurality of waveguides.

4. The method of claim 3 wherein the first optical coupler includes an off-axis diffractive lens.

5. The method of claim 3 wherein the first optical coupler includes a mirror.

6. The method of claim 3 wherein the first optical coupler includes a bent waveguide.

7. The method of claim 3 further comprising further coupling light, by a second optical coupler, from the waveguide to an optical receiver on the second switching chiplet.

8. The method of claim 3 wherein light from the waveguide is coupled to the second switching chiplet by a photodiode.

9. The method of claim 8 wherein the photodiode is within the PWSI.

10. The method of claim 1 wherein the at least two switching chiplets include a serial interface.

11. The method of claim 10 further comprising converting a first serialized electrical data from the serial interface to serialized optical data.

12. The method of claim 11 wherein the converting is based on an electrical-to-optical (E/O) conversion.

13. The method of claim 12 wherein the E/O conversion occurs within the PWSI.

14. The method of claim 11 wherein the switching includes reconverting the serialized optical data to a second serialized electrical data.

15. The method of claim 14 wherein the reconverting is based on an optical-to electrical (O/E) conversion.

16. The method of claim 15 wherein the O/E conversion occurs within the PWSI.

17. The method of claim 1 wherein the coupling and the switching are based on wafer-level co-packaged optics.

18. The method of claim 1 wherein the coupling is based on a network topology.

19. An apparatus for switching comprising:
a photonic wafer-scale interposer (PWSI), wherein the PWSI includes a plurality of waveguides, and wherein a front side of the PWSI is bonded to at least two switching chiplets;
a first switching chiplet within the at least two switching chiplets, wherein the first switching chiplet is coupled to a first optical emitter;
a second switching chiplet within the at least two switching chiplets;
an optical coupler, wherein the optical coupler couples light from the first optical emitter to a first waveguide within the plurality of waveguides; and
a photodiode, wherein the photodiode couples light from the first waveguide to the second switching chiplet.

20. A system for switching comprising:
a photonic wafer-scale interposer (PWSI), wherein the PWSI includes a plurality of waveguides, and wherein a front side of the PWSI is bonded to at least two switching chiplets;
a first switching chiplet within the at least two switching chiplets, wherein the first switching chiplet is coupled to a first optical emitter;
a second switching chiplet within the at least two switching chiplets;
an optical coupler, wherein the optical coupler couples light from the first optical emitter to a first waveguide within the plurality of waveguides; and
a photodiode, wherein the photodiode couples light from the first waveguide to the second switching chiplet, wherein the system, when a data request from a sending node within an external network is sent to the first switching chiplet, is configured to:
switch the data request to the second switching chiplet; and
transfer the data request, by the second switching chiplet, to a receiving node within the external network.
